(19) United States
(12) Patent Application Publication
(10) Pub. No.: US 2006/0151779 A1
(43) Pub. Date: Jul. 13, 2006

(54) Novel thiophene-thiazole derivatives and organic thin film transistors using the same

(75) Inventors: Eun Kyung Lee, Seoul (KR); Joo Young Kim, Gyeonggi-do (KR); Bang Lin Lee, Gyeonggi-do (KR); Kook Min Han, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-Do (KR)

(21) Appl. No.: 11/146,146

(22) Filed: Jun. 7, 2005

(30) Foreign Application Priority Data
Jan. 7, 2005 (KR) 2005-1757

(51) Int. Cl. H01L 51/00

(52) U.S. Cl. 257/40; 257/66; 548/100

(57) ABSTRACT

Novel thiophene-thiazole derivatives and organic thin film transistors using the derivatives. The thiophene-thiazole derivatives are organic polymer semiconductor materials in which a thiophene having p-type semiconductor characteristics is joined to a thiazole having n-type semiconductor characteristics in an alternating manner to have a head-to-tail structure. The use of the thiophene-thiazole derivatives as materials for an organic active layer enables fabrication of organic thin film transistors with low leakage current, high charge carrier mobility and high on/off current ratio.

### BACKGROUND OF THE INVENTION

This non-provisional application claims priority under 35 U.S.C. § 119(a) on Korean Patent Application No. 2005-0001757 filed on Jan. 7, 2005, which is herein expressly incorporated by reference.

1. Field of the Invention

The embodiments of the present invention relate to novel thiophene-thiazole derivatives and organic thin film transistors using the derivatives. More preferably, the embodiments of the present invention relate to organic polymer semiconductor materials in which a thiophene having p-type semiconductor characteristics is joined to a thiazole having n-type semiconductor characteristics in an alternating manner such that the materials have a head-to-tail structure in their side chains.

2. Description of the Related Art

General organic thin film transistors (OTFTs) comprise a substrate, a gate electrode, an insulating layer, source/drain electrodes, and a channel layer. Organic thin film transistors are classified into bottom-contact (BC) OTFTs wherein a channel layer is formed on source and drain electrodes, and top-contact (TC) OTFTs wherein metal electrodes are formed on a channel layer by mask deposition.

Inorganic semiconductor materials, such as silicon (Si), have been commonly used as materials for channel layers of OTFTs. However, since the preparation of such inorganic semiconductor materials involves high costs and requires a high-temperature vacuum process to fabricate OTFTs, organic semiconductor materials are currently replacing inorganic semiconductor materials in order to fabricate large area, flexible displays at reduced costs.

Recently, studies on organic semiconductor materials for channel layers of OTFTs have been actively undertaken and the characteristics of the devices have been reported. Of these, a great deal of research is currently concentrated on low molecular weight materials and oligomers, e.g., melocyanines, phthalocyanines, perylenes, pentacenes, C60, thiophene oligomers, and the like. Lucent Technologies Inc. and 3M Inc. developed devices with charge carrier mobilities as high as 3.2-5.0 cm²/Vs using a pentacene single crystal (Mat. Res. Soc. Symp. Proc. 2003, Vol. 771, L6.5.1-L6.5.11). In addition, CNRS, France, reported a device having a relatively high charge carrier mobility of 0.01-0.1 cm²/Vs and a relatively high on/off current ratio (Iₒₙ/I_{off} ratio) using an oligothiophene derivative (J. Am. Chem. Soc., 1993, Vol. 115, pp. 8716-8721).

However, since the prior art devices are largely dependent on vacuum processes for thin film formation, the fabrication of the devices incurs considerable costs.

On the other hand, high-molecular weight-based organic thin film transistors (charge carrier mobility: 0.01-0.02 cm²/Vs) employing a polythiophene-based material (F8T2) have already been fabricated and tested (PCT Publication WO 00/79617, Science, 2000, vol. 290, pp. 2132-2126). U.S. Pat. No. 6,107,117 discloses the fabrication of an organic thin film transistor with a charge carrier mobility of 0.01-0.04 cm²/Vs by employing polythiophene P3HT (poly(3-alkylthiophene), which is a representative regioregular polymer. Since the regioregular polythiophene P3HT shows a charge carrier mobility of about 0.01 cm²/Vs, but is unstable in air, it has a high off-state leakage current (10⁻⁹A or more), which leads to a low Iₒₙ/I_{off} ratio of 400 or less. Accordingly, P3HT is not applicable to the fabrication of electronic devices.

Further, a poly(thiophene-thiazole) having a head-to-tail structure was reported by T. Yamamoto in Chem. Mater., 16(23), 4616-4618, 2004. However, since this polymer is poorly soluble, it has problems in terms of poor processing properties during wet processes and unsatisfactory TFT characteristics.

Organic polymer semiconductor materials for organic thin film transistors that can be spin-coated at room temperature and simultaneously satisfy the requirements of high charge carrier mobility and low off-state leakage current have not been reported by the cited art.

### SUMMARY OF THE PREFERRED EMBODIMENTS

The embodiments of the present invention have been made in view of the above problems of the related art, and it is an object of the embodiments of the present invention to provide regioregular thiophene-thiazole derivatives in which a thiophene having p-type semiconductor characteristics is joined to a thiazole having n-type semiconductor characteristics in an alternating manner such that the derivatives have a head-to-tail structure, wherein spin-coating at room temperature is enabled and both high charge carrier mobility and low leakage current are simultaneously shown.

In accordance with one aspect of the embodiments of the present invention for achieving at least the above object, there is provided a thiophene-thiazole derivative represented by Formula 1 below:

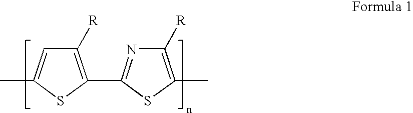

wherein the substituents R, which may be the same or different, are each independently a hydroxyl group, a C₁₋₂₀ linear, branched or cyclic alkyl group, an alkoxyalkyl group, or a cyclic alkoxy group; and n is an integer of 4 to 200.

In accordance with another aspect of the embodiments of the present invention, there is provided an organic thin film transistor fabricated using the polymeric thiopene-thiazole derivative material as a material for an organic active layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a diagram showing the structure of a thiophene-thiazole derivative according to an embodiment of the present invention;

FIG. 2 is a cross-sectional view schematically showing the structure of an organic thin film transistor fabricated in Example 1 as an embodiment of the present invention;

FIG. 3 is a ¹H-NMR spectrum of an organic polymer semiconductor compound prepared in Preparative Example 3; and

FIG. 4 is a graph showing the current transfer characteristics of an organic thin film transistor fabricated in Example 1 as an embodiment of the present invention.

### DESCRIPTION OF THE PREFERRED EMBODIMENTS

The embodiments of the present invention will now be described in more detail with reference to the accompanying drawings.

Embodiments of the present invention provide a thiophene-thiazole derivative, as a polymer semiconductor material, represented by Formula 1 below:

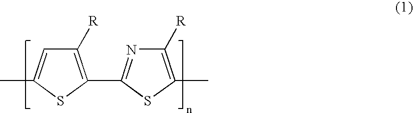

wherein the substituents R, which may be the same or different, are each independently a hydroxyl group, a C₁₋₂₀ linear, branched or cyclic alkyl group, an alkoxyalkyl group, or a cyclic alkoxy group; and n is an integer of 4 to 200.

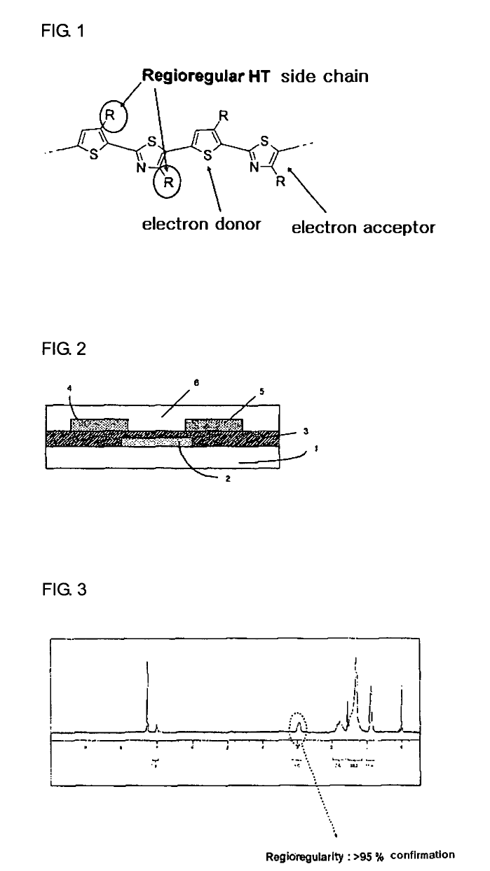

In the structural formula of the compound depicted in FIG. 1, the thiophene unit is an electron donor acting as a p-type semiconductor, while the thiazole unit is an electron acceptor acting as an n-type semiconductor. The two repeating units are arranged in an alternating manner, and particularly, form a regioregular head-to-tail structure in the side chains of the compound. Compounds having such a regioregular structure show high charge carrier mobility due to increased intermolecular p-p stacking.

The thiophene-thiazole derivative of the present invention shows increased intramolecular or intermolecular p-n interaction, based on the structure shown in FIG. 1, resulting in an improvement in π-stacking. As a result, the thiophene-thiazole derivative shows increased charge carrier mobility when applied to the fabrication of organic thin film transistors. In addition, the introduction of the electron acceptor into the polymer semiconductor material of embodiments of the present invention enables control of the bandgap and highest-occupied molecular orbital (HOMO) level in the molecule, providing a relative reduction in the leakage current of the polymer semiconductor material when applied to the fabrication of organic thin film transistors.

The thiophene-thiazole derivative of embodiments of the present invention preferably has a number-average molecular weight of 5,000-80,000.

The thiophene-thiazole derivative of the present invention is prepared by using, as a starting material, a compound of Formula 2 below:

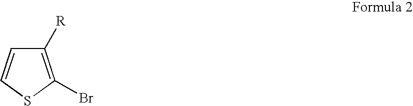

wherein the substituent R is a hydroxyl group, a C₁₋₂₀ linear, branched or cyclic alkyl group, an alkoxyalkyl group, or a cyclic alkoxy group, to obtain a monomer of Formula 3 below:

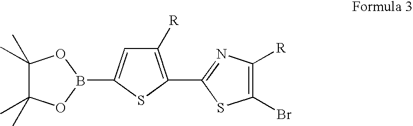

wherein the substituents R are each independently a hydroxyl group, a C₁₋₂₀ linear, branched or cyclic alkyl group, an alkoxyalkyl group, or a cyclic alkoxy group; and polymerizing the monomer.

In a non-limiting embodiment of the present invention, the monomer and the polymer are synthesized by the following Reaction Scheme 1 below:

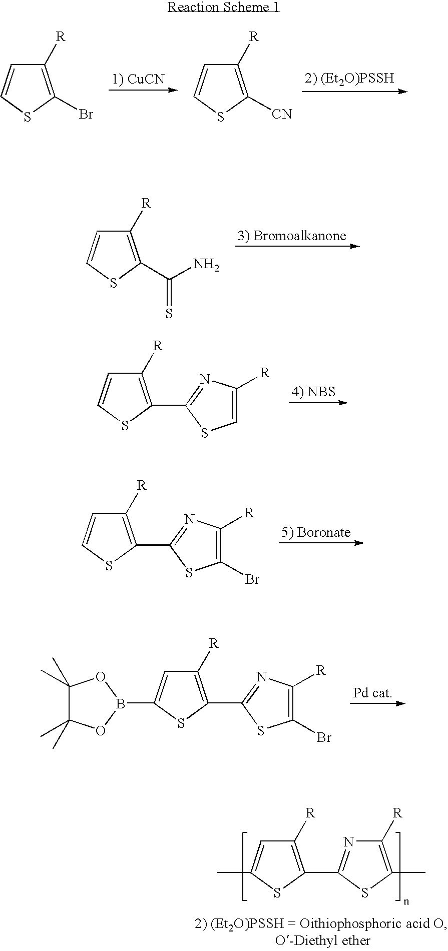

wherein the substituents R, which may be the same or different, are each independently a hydroxyl group, a C₁₋₂₀ linear, branched or cyclic alkyl group, an alkoxyalkyl group, or a cyclic alkoxy group.

Specifically, the thiophene-thiazole derivative of Formula 1 according to embodiments of the present invention can be prepared by subjecting the monomer of Formula 3 to a condensation reaction generally known as the Suzuki coupling. The condensation is preferably carried out under a nitrogen atmosphere at 50-130° C. for 2-24 hours. At this time, toluene, dimethoxy ether, tetrahydrofuran, dimethylformamide, water, etc., can be used as a solvent.

Further, the polymer semiconductor material of the present invention can be synthesized in the presence of a palladium catalyst represented by any one of Formulae 4 to 6 below:

Formula 4

PdL₄

wherein L is a ligand selected from the group consisting of triphenylphosphine (PPh₃), triphenylarsine (AsPh₃), triphenylphosphite (P(OPh)₃), diphenylphosphinoferrocene (dppf), diphenylphosphino butane (dppb), acetate (OAc), and dibenzylideneacetone (dba);

Formula 5

PdL₂X₂

wherein L is as defined in Formula 4, and X is I, Br or Cl; or

Formula 6

PdL₂

wherein L is as defined in Formula 4.

Examples of thiophene-thiazole derivatives that can be synthesized by the Suzuki coupling reaction include compounds represented by Formulae 7 and 8 below:

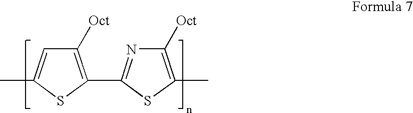

wherein Oct is an octyl group, and n is an integer of 4 to 200; and

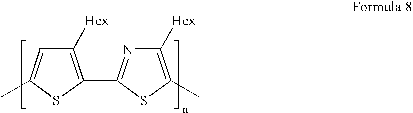

wherein Hex is a hexyl group, and n is an integer of 4 to 200.

The thiophene-thiazole derivative of embodiments of the present invention can be used as a novel organic semiconductor material for the active layer of the OTFT shown in FIG. 2.

An embodiment of the present invention provides a top-contact organic thin film transistor (not shown) having a structure of a substrate/a gate electrode/a gate insulating layer/an organic active layer/source-drain electrodes, or a bottom-contact organic thin film transistor having a structure of a substrate 1/a gate electrode 2/a gate insulating layer 3/source-drain electrodes 4 and 5/an organic active layer 6, as schematically shown in FIG. 2, but the organic thin film transistor of embodiments of the present invention is not limited to these structures.

At this time, the thiophene-thiazole derivative of embodiments of the present invention can be used to form the organic active layer by screen printing, printing, spin coating, dipping, or ink spraying.

The substrate 1 can be made of, but is not limited to, glass, polyethylenenaphthalate (PEN), polyethyleneterephthalate (PET), polycarbonate, polyvinylalcohol, polyacrylate, polyimide, polynorbomene, polyethersulfone (PES), and the like.

The gate electrode 2 can be made of common metals. Specific examples of such metals include, but are not limited to, gold (Au), silver (Ag), aluminum (Al), nickel (Ni), chromium (Cr), indium tin oxide (ITO), and the like.

The gate insulating layer 3 constituting the OTFT can be made of common high-dielectric constant insulators. Specific examples of suitable insulators include, but are not limited to: ferroelectric insulators selected from the group consisting of Ba_{0.33}Sr_{0.66}TiO₃ (BST), Al₂O₃, Ta₂O₅, La₂O₅, Y₂O₃, and TiO₂; inorganic insulators selected from the group consisting of PbZr_{0.33}Ti_{0.66}O₃ (PZT), Bi₄Ti₃O₁₂, BaMgF₄, SrBi₂(TaNb)₂O₉, Ba(ZrTi)O₃ (BZT), BaTiO₃, SrTiO₃, Bi₄Ti₃O₁₂, SiO₂, SiNₓ, and AION; or organic insulators selected from the group consisting of polyimides, benzocyclobutenes (BCBs), parylenes, polyacrylates, polyvinylalcohols, and polyvinylphenols.

The source-drain electrodes 4 and 5 can be made of common metals. Specific examples of such metals include, but are not limited to, gold (Au), silver (Ag), aluminum (Al), nickel (Ni), indium tin oxide (ITO), and the like.

Embodiments of the present invention will now be described in more detail with reference to the following examples. However, these examples are given for the purpose of illustration and are not to be construed as limiting the scope of the invention.

### Preparative Example 1

### Synthesis of 5-bromo-4-octyl-2-(3-octyl-thiophene-2-yI)-thiazole

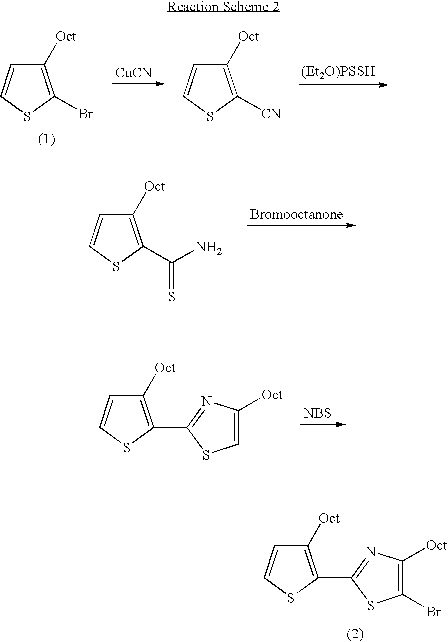

20.0 g (81 mmol) of 2-bromo-3-octylthiophene was reacted with an excess of CuCN to obtain 5.3 g of 2-cyano-3-octylthiophene (yield: 34%). The obtained product was reacted with an excess of dithiophosphoric acid O,O′-diethyl ether (2.5 eq.) in THF for about 12 hours under heating to give 2.9 g of 2-thioamino-3-ctylthiophene (yield: 45%), followed by reaction with 1.2 equivalents of bromooctanone, to obtain 1.4 g of 2-thiazole-(3′-octyl)-3-octylthiophene (yield: 32%). The obtained product was reacted with N-bromosuccinimide to afford 1.32 g of 5-bromo-4-octyl-2-(3-octyl-thiophen-2-yl)-thiazole (2) (yield: 82%).

¹H-NMR (300 MHz, CDCI₃) δ (ppm) 0.89 (6H), 1.35 (20H), 1.68 (4H), 2.73 (2H), 2.83 (2H), 6.92 (1H), 7.26 (1H).

### Preparative Example 2

### Synthesis of 5-bromo-4-octyl-2-(3-octyl-4-dioxoboranyl-thiophene-2-yl)thiazole

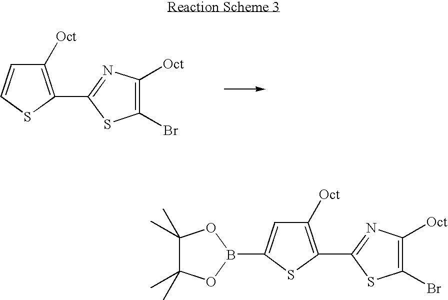

2 g (4.25 mmol) of 5-bromo-4-octyl-2-(3-octyl-thiophen-2-yl)-thiazole was dissolved in 25 ml of THF, and then cooled to −80° C. To the solution was slowly added 3.198 ml (6.375 mmol) of lithium diisopropylamide. After stirring for 30 minutes, 1.186 g (6.375 mmol) of 2-isopropoxy-4,4′,5,5′-tetramethyl-1,3,2-dioxoborolane was slowly added at −80° C. The reaction temperature was gradually elevated to room temperature with stirring for 5 hours. The reaction was quenched by the addition of water. The reaction mixture was extracted with chloroform, washed with water several times, dried over magnesium sulfate, and filtered. The obtained filtrate was evaporated to remove the solvents. The crude product was purified by chromatography to afford 1.2 g of 5-bromo-4-octyl-2-(3-octyl-4-dioxoboranyl-thiophen-2-yl)-thiazole (yield: 47%)

¹H NMR (300 MHz, CDCI₃) δ (ppm) 0.88 (6H), 1.3 (34H), 1.67 (4H), 2.87 (2H), 2.99 (2H), 6.98(1H)

### Preparative Example 3

### Synthesis of 5-methyl-2-(5-methyl-3-octyl-thiophene-2-yl)-4-octyl-thiazole

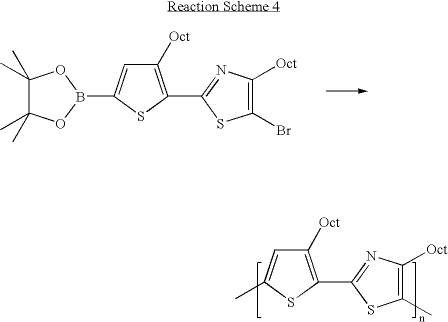

2.36 g (17.07 mmol) of calcium carbonate was dissolved in water, and then 30 ml of THF was added thereto. To the mixture was added a solution of 5-bromo-4-octyl-2-(3-octyl-4-dioxoboranyl-thiophen-2-yl)-thiazole in 20 ml of THF, followed by the addition of 0.296 g (0.256 mmol) of Pd (0). The reaction mixture was stirred at 65° C. for 5-6 hours. After a 10% HCI solution was added to quench the reaction, the reaction mixture was stirred for 24 hours. Extraction was performed to obtain a crude product, followed by the addition of a 10% HCI solution. The mixture was stirred for 24 hours. Extraction was further performed to obtain another crude product, followed by the addition of a 10% ammonium solution. After the mixture was stirred for 24 hours, it was extracted with a chloroform solution and washed with water several times. The crude products were collected and subjected to soxhlet extraction with chloroform to afford 0.2 g of 5-methyl-2-(5-methyl-3-octyl-thiophen-2-yl)-4-octyl-thiazole (yield: 30%). The ¹H-NMR spectrum of the title compound is shown in FIG. 3.

¹H NMR (300 MHz, CDCI₃) δ (ppm) 0.88 (6H), 1.3 (20H), 1.77 (4H), 2.95 (4H), 7.00 (1H)

### Example 1

### Fabrication of an Organic Thin Film Transistor using Thiophene-Thiazole Derivative

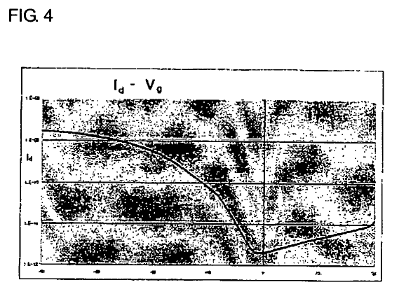

First, chromium was deposited on a plastic substrate that had been previously washed, by a sputtering process, to form a gate electrode having a thickness of 1,000 Å. Thereafter, SiO₂ was deposited on the gate electrode by a CVD process to form a 1,000 Å-thick gate insulating film. The substrate was washed with isopropyl alcohol for 10 minutes and dried before subsequent deposition of an organic semiconductor material. The resulting structure was dipped in a 10 mM octadecyltrichlorosilane solution in hexane for 30 seconds, washed with acetone, and dried. Separately, the thiophene-thiazole derivative prepared in Preparative Example 3 was dissolved in toluene to obtain a 2 wt% solution. The solution was applied to the dried structure at 1,000 rpm to a thickness of 700 Å by spin coating, and baked under an argon atmosphere at 100° C. for one hour. ITO, as a material for source-drain electrodes, was deposited on the organic active layer to a thickness of 1,200 Å by sputtering to 5 fabricate a top-contact OTFT transistor. The charge carrier mobility of the device was measured. The current transfer characteristics of the device were measured using a semiconductor characterization system (4200-SCS, KEITHLEY), and a curve was plotted (FIG. 4). The obtained results are shown in Table 1. The charge carrier mobility was calculated from the following current equations in the saturation region using the current transfer curves.

Specifically, the charge carrier mobility was calculated from the slope of a graph representing the relationship between (I_{SD})^{1/2} and V_{G} from the following current equations in the saturation region:

$${I}_{SD} = \frac{{WC}_{0}}{2 L} μ {( {V}_{G} - {V}_{T} )}^{2}$$

$$\sqrt{{I}_{SD}} = \sqrt{\frac{μ {C}_{0} W}{2 L}} ( {V}_{G} - {V}_{T} )$$

$$slope = \sqrt{\frac{{μC}_{0} W}{2 L}}$$

$${μ}_{FET} = {( slope )}^{2} \frac{2 L}{{C}_{0} W}$$

In the above equations, I_{SD}: source-drain current, μ and μ_{FET}: charge carrier mobility, C_{O}: capacitance of the oxide film, W: channel width, L: channel length; V_{G}: gate voltage, and V_{T}: threshold voltage.

The off-state leakage current (I_{off}) is a current flowing in the off-state, and was determined from the minimum current in the off-state.

### Comparative Example 1

An organic thin film transistor was fabricated in the same manner as in Example 1, except that poly(3-alkylthiophene) (Lucent Technology Inc.) was used. The current transfer characteristics of the device were measured using a semiconductor characterization system (4200-SCS, KEITHLEY). The measured value, charge carrier mobility, and off-state leakage current are shown in Table 1.

### Comparative Example 2

An organic thin film transistor was fabricated in the same manner as in Example 1, except that poly(thiophene-4-alkylthiazole) (HT-Th-4ATz, see Chem. Mater., 16(23); 4616-4618, 2004) was used. The current transfer characteristics of the device were measured using a semiconductor characterization system (4200-SCS, KEITHLEY). The measured value, charge carrier mobility, and off-state leakage current are shown in Table 1.

TABLE 1

| | Charge carrier | Off-state | |
|---|---|---|---|
| | mobility | leakage | |
| Organic active layer | (cm²/V · s) | current (A) | Iₒₙ/I_{off} ratio |
| Example 1 | 0.01 | 2-5 × 10⁻¹² | 10³ |
| Comparative Example 1 | 0.01 | 1 × 10⁻⁹ | 100 |
| Comparative Example 2 | 0.0025 | 1 × 10⁻⁹ | 200 |

As can be seen from the data shown in Table 1, the thiophene-thiazole derivative of embodiments of the present invention showed a charge carrier mobility of 0.01 cm²/Vs, a leakage current of 2-5×10⁻¹² A, and an on/off current ratio of 1.0×10³. Accordingly, the results demonstrate that the thiophene-thiazole derivative of the present invention is very useful in the fabrication of OTFTs.

As apparent from the foregoing, the thiophene-thiazole derivative of embodiments of the present invention is a polymer organic semiconductor material with a novel structure. In addition, since the thiophene-thiazole derivative can be spin-coated at room temperature, is stable, and shows high charge carrier mobility and low off-state leakage current, it can be used as a material for an active layer of an OTFT.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A thiophene-thiazole derivative represented by Formula 1: 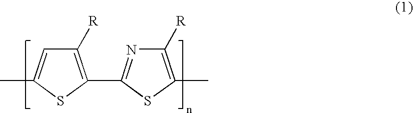
wherein substituents R, which may be the same or different, are each independently a hydroxyl group, a C₁₋₂₀ linear, branched or cyclic alkyl group, an alkoxyalkyl group, or a cyclic alkoxy group; and n is an integer of 4 to 200.

2. The thiophene-thiazole derivative according to claim 1, wherein the substituents R are arranged in a head-to-tail structure.

3. The thiophene-thiazole derivative according to claim 1, wherein the derivative is prepared by using, as a starting material, a compound of Formula 2: 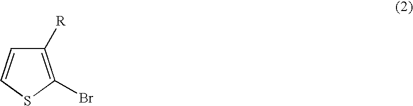
wherein substituent R is a hydroxyl group, a C₁₋₂₀ linear, branched or cyclic alkyl group, an alkoxyalkyl group, or a cyclic alkoxy group, to obtain a monomer of Formula 3: 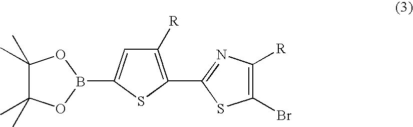
wherein substituents R are each independently a hydroxyl group, a C_{1×20} linear, branched or cyclic alkyl group, an alkoxyalkyl group, or a cyclic alkoxy group; and condensing the monomer in the presence of a catalyst compound represented by any one of Formulae 4 to 6:
PdL4 (4)
wherein L is a ligand selected from the group consisting of triphenylphosphine, triphenylarsine, triphenylphosphite, diphenylphosphinoferrocene, diphenyiphosphino butane, acetate, and dibenzylideneacetone;
PdL₂X₂ (5)
wherein L is as defined in Formula 4, and X is I, Br or Cl; and
PdL₂ (6)
wherein L is as defined in Formula 4.

4. The thiophene-thiazole derivative according to claim 1, wherein the derivative is a compound represented by Formula 7: 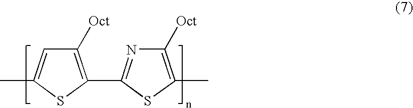
wherein Oct is an octyl group, and n is an integer of 4 to 200; or Formula 8: 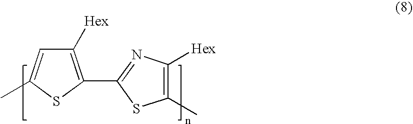
wherein Hex is a hexyl group, and n is an integer of 4 to 200.

5. An organic thin film transistor comprising a substrate, a gate electrode, a gate insulating film, an organic active layer and source/drain electrodes wherein the organic active layer is made of the thiophene-thiazole derivative according to claim 1.

6. The organic thin film transistor according to claim 5, wherein the organic active layer is formed into a thin film by screen printing, printing, spin coating, dipping, or ink spraying.

7. The organic thin film transistor according to claim 5, wherein the gate insulating layer is made of a ferroelectric insulator selected from the group consisting of Ba_{0.33}Sr_{0.66}TiO₃, Al₂O₃, Ta₂O₅, La₂O₅, Y₂O₃, and TiO₂; an inorganic insulator selected from the group consisting of PbZr_{0.33}Ti_{0.66}O₃, Bi₄Ti₃O₁₂, BaMgF₄, SrBi₂(TaNb)₂O₉, Ba(ZrTi)O₃, BaTiO₃, SrTiO₃, Bi₄Ti₃O₁₂, SiO₂, SiNₓ, and AION; or an organic insulator selected from the group consisting of polyimides, benzocyclobutenes, parylenes, polyacrylates, polyvinylalcohols, and polyvinylphenols.

8. The organic thin film transistor according to claim 5, wherein the substrate is made of a material selected from the group consisting of glass, polyethylenenaphthalate, polyethyleneterephthalate, polycarbonate, polyvinylalcohol, polyacrylate, polyimide, polynorbomene, and polyethersulfone.

9. The organic thin film transistor according to claim 5, wherein the gate electrode and source-drain electrodes are made of a material selected from the group consisting of gold, silver, aluminum, nickel, chromium, and indium tin oxide.

10. The thiophene-thiazole derivative according to claim 1, wherein the derivative has a number-average molecular weight of 5,000-80,000.
